(19) United States
(12) Patent Application Publication
(10) Pub. No.: US 2015/0130074 A1
(43) Pub. Date: May 14, 2015

(54) SEMICONDUCTOR DEVICE AND METHOD FOR FORMING THE SAME

(71) Applicant: SK hynix Inc., Icheon-si (KR)

(72) Inventor: Wang Su KIM, Icheon-si (KR)

(73) Assignee: SK hynix Inc., Icheon-si (KR)

(21) Appl. No.: 14/172,350

(22) Filed: Feb. 4, 2014

(30) Foreign Application Priority Data
Nov. 12, 2013 (KR) 10-2013-0136652

(51) Int. Cl. H01L 23/538; H01L 21/768

(52) U.S. Cl. CPC H01L 23/5384; H01L 23/5386; H01L 21/76877
USPC 257/774; 257/773; 438/638

(57) ABSTRACT

A semiconductor device may include: a wiring layer formed over an interlayer dielectric layer; and one or more wiring characteristic control parts extended from the wiring layer into the interlayer dielectric layer. The bottom of the one or more wiring characteristic control parts may be positioned at a higher level than the bottom of the interlayer dielectric layer.

### CROSS-REFERENCES TO RELATED APPLICATION

The present application claims priority under 35 U.S.C. §119(a) to Korean application number 10-2013-0136652, filed on Nov. 12, 2013, in the Korean Intellectual Property Office, which is incorporated herein by reference in its entirety.

### BACKGROUND

1. Technical Field

Various embodiments relate to a semiconductor device and a method for forming the same, and more particularly, to a semiconductor device capable of easily changing electrical characteristics of a wiring structure and a method for forming the same.

2. Related Art

Recently, with the increase in integration degree and the decrease in size of semiconductor devices, memory cells are arranged in a stacked structure. Thus, wirings for electrically coupling the respective cells are also formed in a multilayer structure capable of facilitating wiring design.

When such a multilayer wiring structure is applied, the degree of freedom for wiring design may be increased, and wiring resistance and capacitance may be flexibly set.

FIG. 1 is a diagram illustrating a typical wiring structure of a semiconductor device.

Referring to FIG. 1, the typical wiring structure includes a first wiring layer 10, an interlayer dielectric layer (not illustrated), a second wiring layer 20, and a contact 30. The contact 30 is formed in the interlayer dielectric layer so as to couple the first and second wiring layers 10 and 20.

When the electrical characteristic of the multilayer wiring structure must be changed, the wiring area or shape of the multilayer wiring structure must be changed.

FIG. 2 is a diagram illustrating a wiring structure of a conventional semiconductor device. The wiring structure illustrated in FIG. 2 may be provided when the capacitance of the typical wiring structure of FIG. 1 must be increased.

The wiring structure of FIG. 2 may include a first wiring layer 10, an interlayer dielectric layer (not illustrated), a second wiring layer 20a, and a contact 30, like the wiring structure illustrated in FIG. 1. In this wiring structure, the second wiring layer 20a may be formed in a zigzag shape, instead of a line shape. As the second wiring layer 20a is formed in a zigzag shape, a large amount of capacitance may be generated from the second wiring layer 20a.

FIG. 3 is a diagram illustrating a wiring structure of another conventional semiconductor device. The wiring structure illustrated in FIG. 3 may be provided when the resistance of the typical wiring structure illustrated in FIG. 1 must be reduced.

The wiring structure of FIG. 3 may include a first wiring layer 10, an interlayer dielectric layer (not illustrated), a second wiring layer 20b, and a contact 30, like the wiring structure illustrated in FIG. 1. In this wiring structure, the second wiring layer 20b has a larger width than the second wiring layer 20 of FIG. 1. As the second wiring layer 20b has a large width, the resistance may be easily reduced.

However, in the wiring structures illustrated in FIGS. 2 and 3, the areas of the wiring layers are inevitably increased according to the electrical characteristic.

### SUMMARY

Various embodiments are directed to a semiconductor device having a wiring structure which is capable of easily changing electrical characteristics without increasing an area occupied by a wiring layer.

In an embodiment, a semiconductor device may include: a wiring layer formed over an interlayer dielectric layer; and one or more wiring characteristic control parts extended from the wiring layer into the interlayer dielectric layer. The bottom of the one or more wiring characteristic control parts may be positioned at a higher level than the bottom of the interlayer dielectric layer.

In an embodiment, a semiconductor device may include: a first wiring layer; an interlayer dielectric layer formed over the first wiring layer; one or more wiring characteristic control parts formed in the interlayer dielectric layer; and a second wiring layer formed over the interlayer dielectric layer including the one or more wiring characteristic control parts. The one or more wiring characteristic control parts formed in the interlayer dielectric layer may be extended from the bottom of the second wiring layer toward the first wiring layer, and the bottom of the one or wiring characteristic control parts may be positioned at a higher level than the bottom of the interlayer dielectric layer.

In an embodiment, a method for forming a semiconductor device may include the steps of: providing a semiconductor substrate having a lower structure; forming an interlayer dielectric layer over the semiconductor substrate; forming one or more partial via holes in the interlayer dielectric layer such that the bottom of the one or more via holes is positioned at a higher level than the bottom of the interlayer dielectric layer; forming one or more wiring characteristic control parts by burying a conductive material in the one or more partial via holes; and forming an upper wiring layer over the interlayer dielectric layer including the one or more characteristic control parts.

### BRIEF DESCRIPTION OF THE DRAWINGS

Features, aspects, and embodiments are described in conjunction with the attached drawings, in which:

FIG. 1 is a diagram illustrating a typical wiring structure of a semiconductor device;

FIG. 2 is a diagram illustrating a wiring structure of a conventional semiconductor device;

FIG. 3 is a diagram illustrating a wiring structure of another conventional semiconductor device;

FIG. 4A schematically illustrates a semiconductor device according to an embodiment;

FIG. 4B is a cross-sectional view of the semiconductor device of FIG. 4A;

FIG. 5A schematically illustrates a semiconductor device according to an embodiment;

FIG. 5B is a cross-sectional view of the semiconductor device of FIG. 5A;

FIGS. 6A and 6B schematically illustrate semiconductor devices according to other embodiments; and

FIG. 7 is a flowchart illustrating a method for forming a semiconductor device according to an embodiment.

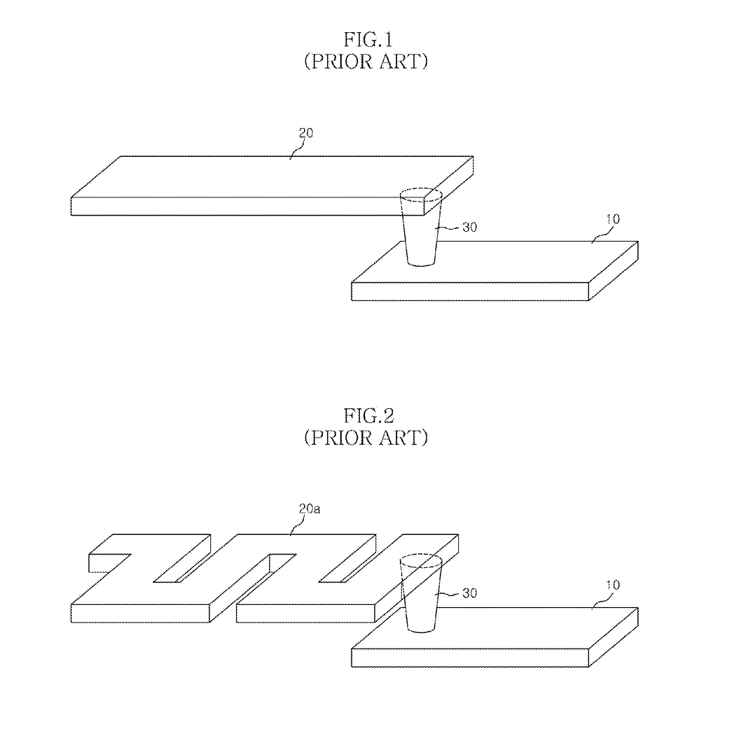

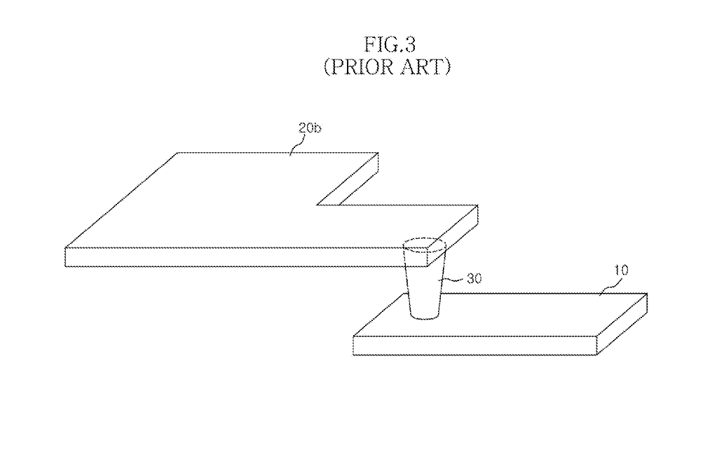

### DETAILED DESCRIPTION

Hereinafter, a semiconductor device and a method for forming the same according to the present invention will be described below with reference to the accompanying drawings through various examples of embodiments.

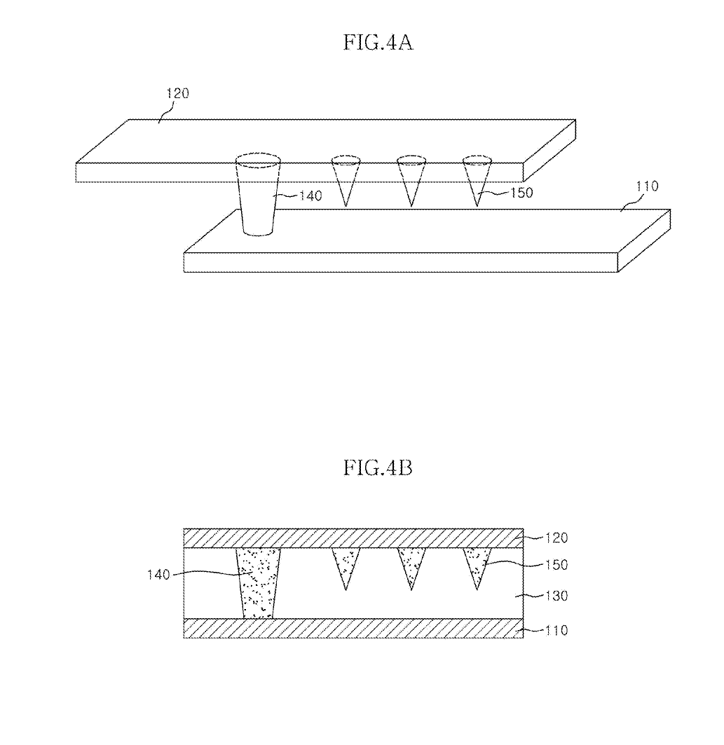

Referring to FIGS. 4A and 4B, a semiconductor device according to an embodiment may include a first wiring layer 110, an interlayer dielectric layer 130, a second wiring layer 120, a contact 140, and one or more wiring characteristic control parts 150. The interlayer dielectric layer 130 is formed over the first wiring layer 110. The second wiring layer 120 is formed over the interlayer dielectric layer 130. The contact 140 is formed in the interlayer dielectric layer 130 so as to electrically couple the first and second wiring layers 110 and 120. The one or more wiring characteristic control parts 150 are formed in the interlayer dielectric layer 130 so as to control the electrical characteristic of the wiring structure.

Specifically, the first and second wiring layers 110 and 120 may be formed of a conductive material. The first and second wiring layers 110 and 120 may be formed in a line shape, for example.

The interlayer dielectric layer 130 may be formed of an insulating material capable of insulating the first and second wiring layers 110 and 120 from each other, for example, oxide or nitride.

The contact 140 serves to electrically couple the first and second wiring layers 110 and 120. The contact 140 may be formed through the following process: a contact hole is formed in the interlayer dielectric layer 130 so as to expose the top surface of the first wiring layer 110 and a conductive material is buried in the contact hole.

The wiring characteristic control part 150 is formed in the interlayer dielectric layer 130, like the contact 140. The wiring characteristic control part 150 illustrated in FIGS. 4A and 4B may increase the capacitance of the wiring structure, for example, the multilayer wiring structure of the first and second wiring layers 110 and 120.

The wiring characteristic control parts 150 may be formed through the following process: a plurality of partial via holes are formed in the interlayer dielectric layer 130 so as not to expose the top surface of the first wiring layer 110 and a conductive material is buried in the partial via holes.

The partial via holes formed in the interlayer dielectric layer 130 are extended from the bottom of the second wiring layer 120 to the first wiring layer 110 so as to be insulated from the first wiring layer 110. The depth of the via hole may be set according to the area of the top surface thereof. Thus, the size of the top surface of the via hole may be set according to the change in electrical characteristic, when the partial via holes are formed.

In other words, the wiring characteristic control parts 150 according to these embodiments may be formed in the interlayer dielectric layer 130 so as to be insulated from the first wiring layer 110 by the interlayer dielectric layer 130, while electrically coupled to the second wiring layer 120.

Thus, capacitance may be generated between the plurality of wiring characteristic control parts 150 formed by burying a conductive material in the respective partial via holes. Therefore, the capacitance of the wiring structure may be increased.

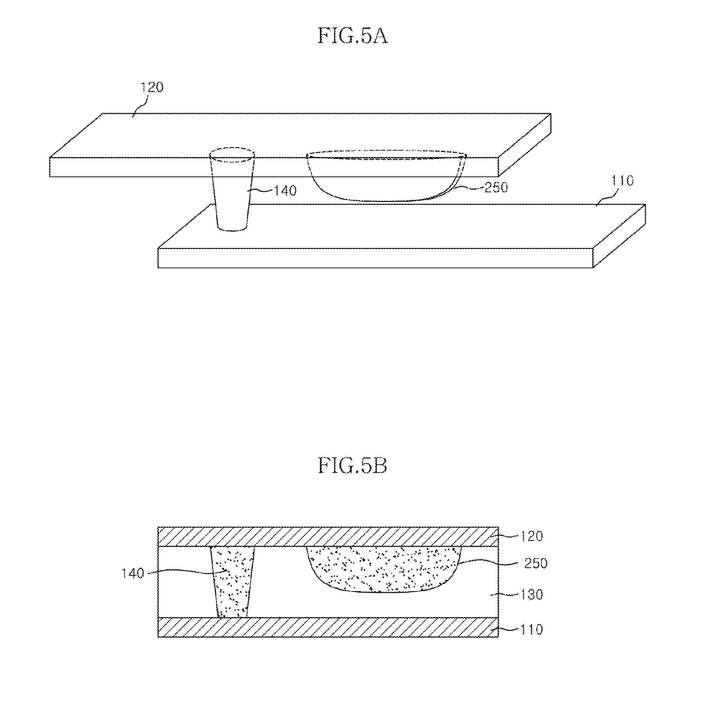

Referring to FIGS. 5A and 5B, a semiconductor device according to an embodiment will be described as follows.

As illustrated in FIGS. 5A and 5B, the semiconductor device according to an embodiment includes a first wiring layer 110, an interlayer dielectric layer 130, a second wiring layer 120, a contact 140, and one or more wiring characteristic control parts 250.

The wiring characteristic control parts 250 may be provided to reduce the resistance of the multilayer wiring structure. The wiring characteristic control parts 250 are formed by burying a conductive material in partial via holes formed in the interlayer dielectric layer 130, and the partial via holes are formed in a line shape extended in one direction of the second wiring layer 120.

In other words, the partial via holes may be extended in one direction of the second wiring layer 120, for example, in the longitudinal direction of the second wiring layer 120, and formed in the interlayer dielectric layer 130 so as to be insulated from the first wiring layer 110 by the interlayer dielectric layer 130, while electrically coupled to the second wiring layer 120.

Thus, the wiring characteristic control parts 250 formed by burying a conductive material in the partial via holes may reduce resistance occurring in the multilayer wiring structure.

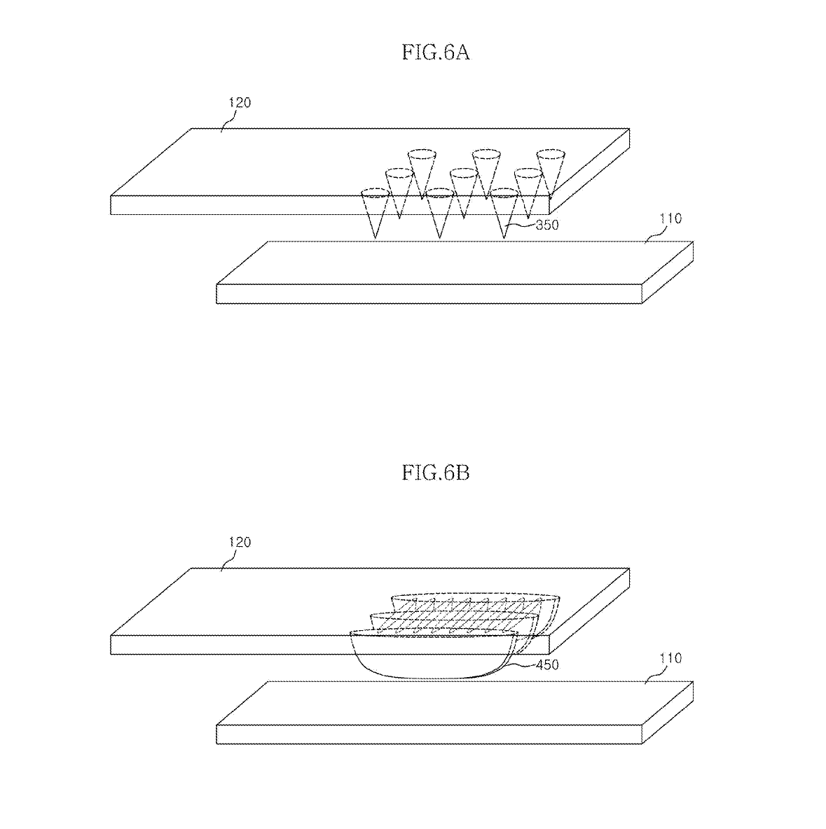

Referring to FIG. 6A, a semiconductor device according to an embodiment may have a plurality of wiring characteristic control parts 350 forming a plurality of rows and columns. Referring to FIG. 6B, a semiconductor device according to an embodiment may have a plurality of wiring characteristic control parts 450 forming a plurality of rows and columns and crossing each other. FIGS. 6A and 6B also illustrate first wiring layer 110 and second wiring layer 120.

Hereafter, a method for forming a wiring structure of a semiconductor device according to an embodiment will be described with reference to the accompanying drawings. In the following descriptions, the semiconductor device illustrated in FIGS. 4A and 4B will be used as an example.

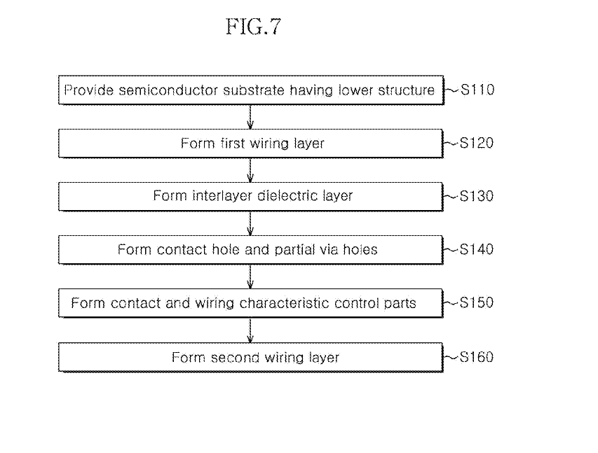

Referring to FIGS. 4A, 4B, and 7, a semiconductor substrate (not illustrated) having a lower structure is provided at step S110. The lower structure may include a word line, a bit line, and a capacitor.

A first wiring layer 110 is formed over the semiconductor substrate having the lower structure at step S120. The first wiring layer 110 may be used as a wiring for electrically coupling an impurity region, a word line, a bit line, or a unit element of the semiconductor substrate to an upper structure formed at an upper layer, but is not limited thereto.

Then, an interlayer dielectric layer 130 is formed over the first wiring layer 110 at step S130, and a contact hole for forming a contact 140 and one or more partial via holes for forming one or more wiring characteristic control parts 150 are formed in the interlayer dielectric layer 130 at steps S140 and S150, respectively.

For example, the contact hole and the partial via holes may be simultaneously or separately formed through the following process: a hard mask pattern (not illustrated) is formed over the interlayer dielectric layer 130 and used as an etch mask to perform an etch process.

During the above-described process, when the contact hole and the partial via holes are formed at the same time, the top surface of the partial via hole may have a smaller area than the top surface of the contact hole. For example, the top surface of the partial via hole may have a smaller diameter than the top surface of the contact hole.

The depth of the contact hole may be set according to the size of the top surface of the contact hole. In the present embodiment, the top surface of the contact hole may be set to such a size that the contact hole within the interlayer dielectric layer 130 exposes the top surface of the first wiring layer. On the other hand, since the top surface of the partial via hole has a smaller area than the top surface of the contact hole, the top surface of the first wiring layer 110 is not exposed, but the bottom of the partial via hole may be disposed within the interlayer dielectric layer 130 even though the partial via hole is formed.

Furthermore, when the contact hole and the partial via holes are separately formed, the contact hole and the partial via holes may be formed by modifying the etch process. For example, when the partial via holes are formed, etch gas may be supplied in a different manner from when the contact hole is formed.

Thus, according to the size and number of the partial via holes formed through the above-described processes, the electrical characteristics of the semiconductor device according to the embodiments may be determined. For example, the capacitance of the multilayer wiring structure including the first and second writing layers 110 and 120 may be increased, or the resistance of the multilayer wiring structure may be reduced.

Then, a conductive material is buried in the contact hole and the partial via holes, and a planarization process is performed until the top surface of the interlayer dielectric layer 130 is exposed. In other words, a contact 140 and wiring characteristic control parts 150 are formed in the interlayer dielectric layer 130.

Then, a second wiring layer 120 is formed on the entire structure, thereby completing the semiconductor device according to the embodiments.

While certain embodiments have been described above, it will be understood to those skilled in the art that the embodiments described are by way of example only. Accordingly, the semiconductor device described herein should not be limited based on the described embodiments. Rather, the semiconductor device described herein should only be limited in light of the claims that follow when taken in conjunction with the above description and accompanying drawings.

What is claimed is:

1. A semiconductor device comprising:
a wiring layer formed over an interlayer dielectric layer; and
one or more wiring characteristic control parts extended from the wiring layer into the interlayer dielectric layer,
wherein the bottom of the one or more wiring characteristic control parts is positioned at a higher level than the bottom of the interlayer dielectric layer.

2. The semiconductor device of claim 1, wherein the plurality of wiring characteristic control parts are arranged at predetermined intervals within the interlayer dielectric layer.

3. The semiconductor device of claim 2, wherein the wiring characteristic control parts are arranged to form one row or column.

4. The semiconductor device of claim 2, wherein the wiring characteristic control parts are arranged to form a plurality of rows and columns.

5. The semiconductor device of claim 2, wherein the wiring characteristic control parts have a line shape extended in one direction of the wiring layer.

6. The semiconductor device of claim 5, wherein the plurality of wiring characteristic control parts are arranged in such a shape to cross each other.

7. A semiconductor device comprising:
a first wiring layer;
an interlayer dielectric layer formed over the first wiring layer;
one or more wiring characteristic control parts formed in the interlayer dielectric layer; and
a second wiring layer formed over the interlayer dielectric layer including the one or more wiring characteristic control parts,
wherein the one or more wiring characteristic control part is only electrically coupled to the second wiring layer.

8. The semiconductor device of claim 7, further comprising a contact formed in the interlayer dielectric layer so as to electrically couple the first and second wiring layers.

9. The semiconductor device of claim 8, wherein the interlayer dielectric layer comprises a contact hole for forming the contact and one or partial via holes for forming the one or more wiring characteristic control parts, and
the one or more partial via holes do not pass through the interlayer dielectric layer.

10. The semiconductor device of claim 9, wherein the plurality of partial via holes are arranged at predetermined intervals within the interlayer dielectric layer.

11. The semiconductor device of claim 10, wherein the partial via holes are arranged to form one row or column.

12. The semiconductor device of claim 10, wherein the partial via holes are arranged to form a plurality of rows and columns.

13. The semiconductor device of claim 10, wherein the partial via holes are formed to extend in one direction of the wiring layer.

14. The semiconductor device of claim 13, wherein the plurality of partial via holes are arranged in a shape to cross each other.

15. The semiconductor device of claim 9, wherein the top surface of the partial via hole has a smaller size than the top surface of the contact hole.

16. A method for forming a semiconductor device, comprising the steps of:
providing a semiconductor substrate having a lower structure;
forming an interlayer dielectric layer over the semiconductor substrate;
forming one or more partial via holes in the interlayer dielectric layer such that the bottom of the one or more via holes is positioned at a higher level than the bottom of the interlayer dielectric layer;
forming one or more wiring characteristic control parts by burying a conductive material in the one or more partial via holes; and
forming an upper wiring layer over the interlayer dielectric layer including the one or more characteristic control parts.

17. The method of claim 16, further comprising the step of forming a lower wiring layer, after the step of providing the semiconductor substrate.

18. The method of claim 17, wherein the step of forming the one or more partial via holes comprises the step of forming a contact hole to pass through the interlayer dielectric layer.

19. The method of claim 17, wherein the step of forming the one or more wiring characteristic control parts comprises the step of burying a conductive material in the contact hole so as to electrically couple the first and second wiring layers.

20. The method of claim 17, wherein the top surface of the partial via hole has a smaller size than the top surface of the contact hole.
